(19) United States
(12) Patent Application Publication
(10) Pub. No.: US 2016/0018678 A1
(43) Pub. Date: Jan. 21, 2016

(54) ORGANIC LIGHT EMITTING DISPLAY DEVICES

(71) Applicant: Samsung Display Co., Ltd., Yongin-city (KR)

(72) Inventors: Dong-Wook CHOI, Hwaseong-si (KR); Jong-Ho CHONG, Hwaseong-si (KR)

(21) Appl. No.: 14/602,704

(22) Filed: Jan. 22, 2015

(30) Foreign Application Priority Data
Jul. 18, 2014 (KR) 10-2014-0090721

(51) Int. Cl. G02F 1/061; H01L 27/32; G02F 1/01

(52) U.S. Cl. CPC G02F 1/061; G02F 1/0147; H01L 27/3232

(57) ABSTRACT

An organic light emitting display device includes a substrate, a display structure disposed on a first face of the substrate, and a light transmission controlling member disposed on a second face of the substrate opposed to the first face, in which the light transmission controlling member includes a shape memory polymer configured to change its shape to control an amount of an external light passing through the light transmission controlling member.

### CROSS-REFERENCE TO RELATED APPLICATION

This application claims priority under 35 U.S.C. §119 to Korean patent Application No. 10-2014-0090721, filed on Jul. 18, 2014, the disclosure of which is hereby incorporated by reference herein in its entirety.

### BACKGROUND

1. Field

The following disclosure relates to organic light emitting display devices. More particularly, the following disclosure relates to organic light emitting display devices including at least one light transmission controlling member.

2. Discussion of the Background

Recently, a transparent organic light emitting display device became one of the prospective next-generation display devices. The transparent organic light emitting display device may include a transparent region and a pixel region. In the transparent organic light emitting display device, an image of an object before or after a transparent region of the transparent organic light emitting display device may be recognized when the transparent organic light emitting display device is in an ON state. In an OFF state of the transparent organic light emitting display device, an image may be displayed in the pixel region of the transparent organic light emitting display device.

However, since the conventional transparent organic light emitting display device may have a substantially same transmittance, and an external light may be always transmitted through the transparent region of the conventional transparent organic light emitting display device, the conventional transparent organic light emitting display device may not implement a black mode. In addition, when the conventional transparent organic light emitting display device is used in an outdoor environment, a legibility of the conventional transparent organic light emitting display device may be reduced.

### SUMMARY

Exemplary embodiments of the present invention provide an organic light emitting display device including at least one light transmission controlling member having a shape memory polymer to control a transmittance of the organic light emitting display device.

Additional features of the invention will be set forth in the description which follows, and in part will be apparent from the description, or may be learned by practice of the invention.

Exemplary embodiments of the present invention include an organic light emitting display device including a substrate, a display structure disposed on a first face of the substrate, and a light transmission controlling member disposed on a second face of the substrate, the second face opposed to the first face, in which the light transmission controlling member includes a shape memory polymer configured to change its shape to control an amount of external light passing through the light transmission controlling member.

According to exemplary embodiments of the present invention, an organic light emitting display device may include a display structure disposed on a first face of the substrate and at least one light transmission controlling member disposed on a second face of the substrate opposed to the first face of the substrate. The light transmission controlling member may include a plurality of protruding portions having a shape memory polymer. When the light transmission controlling member is contracted according to an electric signal applied to the display structure, each of shapes of the protruding portions may vary. A degree of a transmission of an external light may vary according to a degree of the contraction of the light transmission controlling member. More specifically, since the light transmission controlling member and the display structure may share the electric signal, the transmittance of the organic light emitting display device may be simply controlled. Further, only one element for controlling the transmittance of the organic light emitting display device (e.g., the light transmission controlling member) may be additionally formed on the second face of the substrate, so that the organic light emitting display device may have a thickness below a reference value and may display images having various transmittances. According to exemplary embodiments of the present invention, an organic light emitting display device may include a display structure disposed on a first face of the substrate, at least one light transmission controlling member having a shape memory polymer disposed on a second face of the substrate opposed to the first face of the substrate, and a switching device electrically connected to the display structure and the light transmission controlling member. The display structure and the light transmission controlling member may have an ON state and/or an OFF state using the switching device, so that the organic light emitting display device may operate in at least one of a transparent mode, a clear mode, and a black mode.

It is to be understood that both the foregoing general description and the following detailed description are exemplary and explanatory and are intended to provide further explanation of the invention as claimed. Other features and aspects will be apparent from the following detailed description, the drawings, and the claims.

### BRIEF DESCRIPTION OF THE DRAWINGS

The accompanying drawings, which are included to provide a further understanding of the invention and are incorporated in and constitute a part of this specification, illustrate exemplary embodiments of the invention, and together with the description serve to explain the principles of the invention. Illustrative, non-limiting exemplary embodiments will be more clearly understood from the following detailed description taken in conjunction containing the accompanying drawings.

FIG. 1 is a cross-sectional view illustrating an organic light emitting display device according to exemplary embodiments of the present invention.

FIG. 2A is a cross-sectional view illustrating an organic light emitting display device including a light transmission controlling member according to exemplary embodiments of the present invention.

FIG. 2B is a cross-sectional view magnifying a driving region of the organic light emitting display device of FIG. 2A.

FIG. 3A is a cross-sectional view illustrating an organic light emitting display device including a light transmission controlling member according to according to exemplary embodiments of the present invention.

FIG. 3B is a cross-sectional view magnifying a driving region of the organic light emitting display device of FIG. 3A.

FIG. 4 is a perspective view illustrating a white mode of an organic light emitting display device according to exemplary embodiments of the present invention.

FIG. 5 is a perspective view illustrating a red mode of an organic light emitting display device according to exemplary embodiments of the present invention.

FIG. 6 is a perspective view illustrating a black mode of an organic light emitting display device according to exemplary embodiments of the present invention.

FIG. 7 is a cross-sectional view illustrating an organic light emitting display device according to exemplary embodiments of the present invention.

FIG. 8 is a perspective view illustrating a white mode of an organic light emitting display device according to exemplary embodiments of the present invention.

FIG. 9 is a perspective view illustrating a white mode of an organic light emitting display device according exemplary embodiments of the present invention.

FIG. 10 is a perspective view illustrating a red mode of an organic light emitting display device according to exemplary embodiments of the present invention.

FIG. 11 is a perspective view illustrating a red mode of an organic light emitting display device according to exemplary embodiments of the present invention.

FIG. 12 is a perspective view illustrating a black mode of an organic light emitting display device according to exemplary embodiments of the present invention.

### DETAILED DESCRIPTION OF THE ILLUSTRATED EMBODIMENTS

The invention is described more fully hereinafter with reference to the accompanying drawings, in which embodiments of the invention are shown. This invention may, however, be embodied in many different forms and should not be construed as limited to the embodiments set forth herein. Rather, these embodiments are provided so that this disclosure is thorough, and will fully convey the scope of the invention to those skilled in the art. It will be understood that for the purposes of this disclosure, “at least one of X, Y, and Z” can be construed as X only, Y only, Z only, or any combination of two or more items X, Y, and Z (e.g., XYZ, XZ, XYY, YZ, ZZ). Throughout the drawings and the detailed description, unless otherwise described, the same drawing reference numerals are understood to refer to the same elements, features, and structures. The relative size and depiction of these elements may be exaggerated for clarity.

It will be understood that when an element or layer is referred to as being “on”, “connected to” or “coupled to” another element or layer, it can be directly on, connected or coupled to the other element or layer or intervening elements or layers may be present. In contrast, when an element is referred to as being “directly on,” “directly connected to” or “directly coupled to” another element or layer, no intervening elements or layers may be present. Like numbers refer to like elements throughout. As used herein, the term “and/or” may include any and all combinations of one or more of the associated listed items.

It will also be understood that, although the terms first, second, etc. may be used herein to describe various elements, components, regions, layers and/or sections, these elements, components, regions, layers and/or sections are not be limited by these terms. These terms are used to distinguish one element, component, region, layer or section from another region, layer or section. Thus, a first element, component, region, layer or section discussed below could be termed a second element, component, region, layer or section without departing from the teachings of the present invention.

Spatially relative terms, such as “beneath”, “below”, “lower”, “above”, “upper” and the like, may be used herein for ease of description to describe one element or feature's spatial relationship to another element or feature as illustrated in the figures. It will be understood that the spatially relative terms may encompass different orientations of the device in use or operation in addition to the orientation depicted in the figures. For example, if the device in the figures is turned over, elements described as being located “below” or “beneath” other elements or features would then be oriented to be “above” the other elements or features. Thus, the exemplary term “below” can encompass both a relative orientation of above and below with respect to a reference element or feature. The device may be otherwise oriented (e.g., rotated 90 degrees or at other orientations) and the spatially relative descriptors used herein may be interpreted accordingly.

The terminology used herein is for the purpose of describing particular embodiments only and is not intended to be limiting of the invention. As used herein, the singular forms, “a”, “an” and “the” are intended to include the plural forms as well, unless the context clearly indicates otherwise. It will be further understood that the terms “includes” and/or “including”, when used in this specification, specify the presence of stated features, integers, steps, operations, elements, and/or components, but do not preclude the presence or addition of one or more other features, integers, steps, operations, elements, components, and/or groups thereof.

Unless otherwise specified, various terms (including technical and scientific terms) used herein may have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

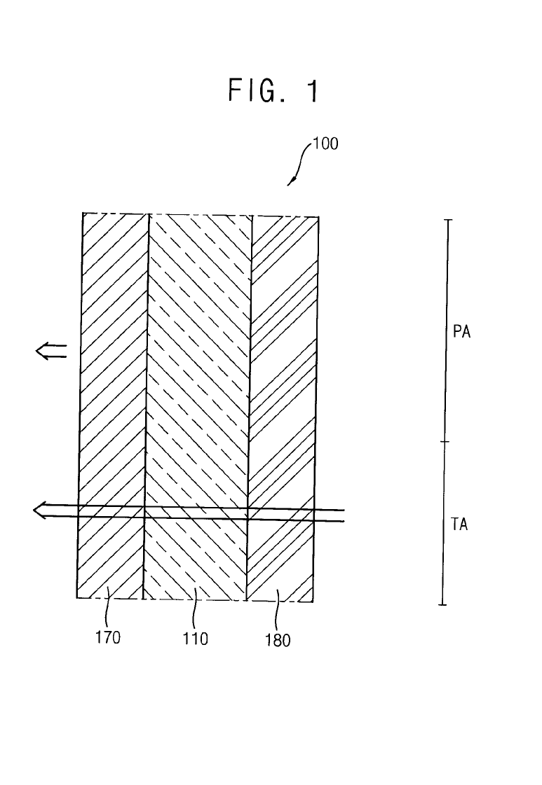

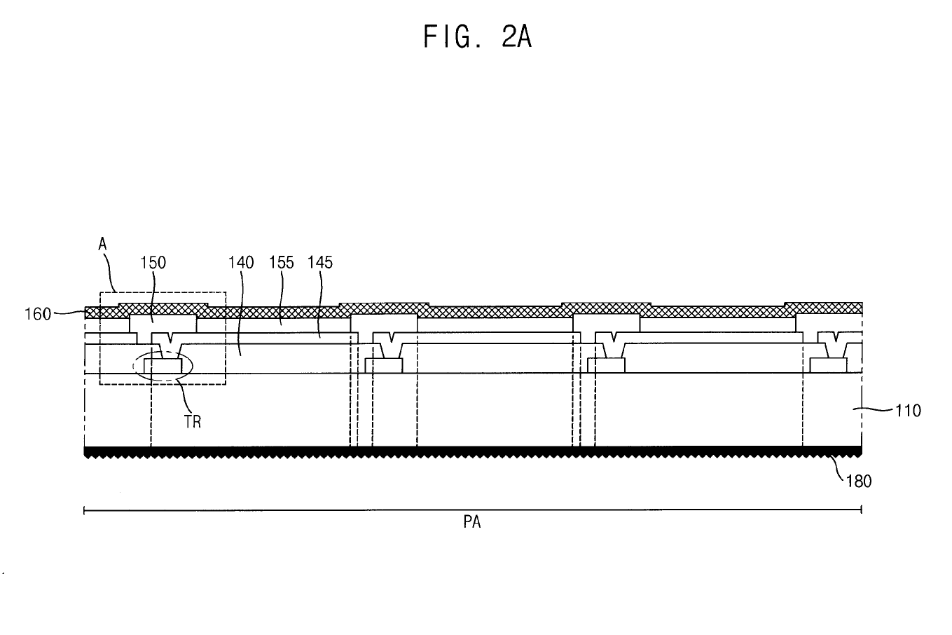

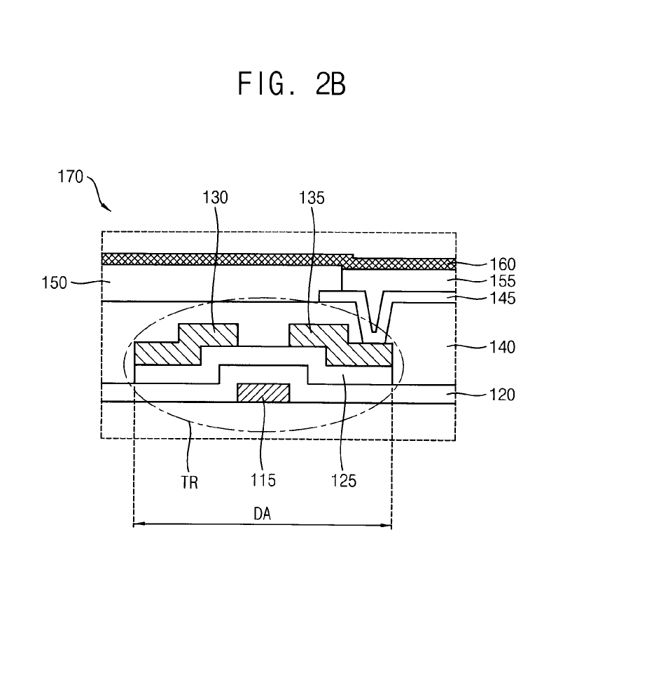

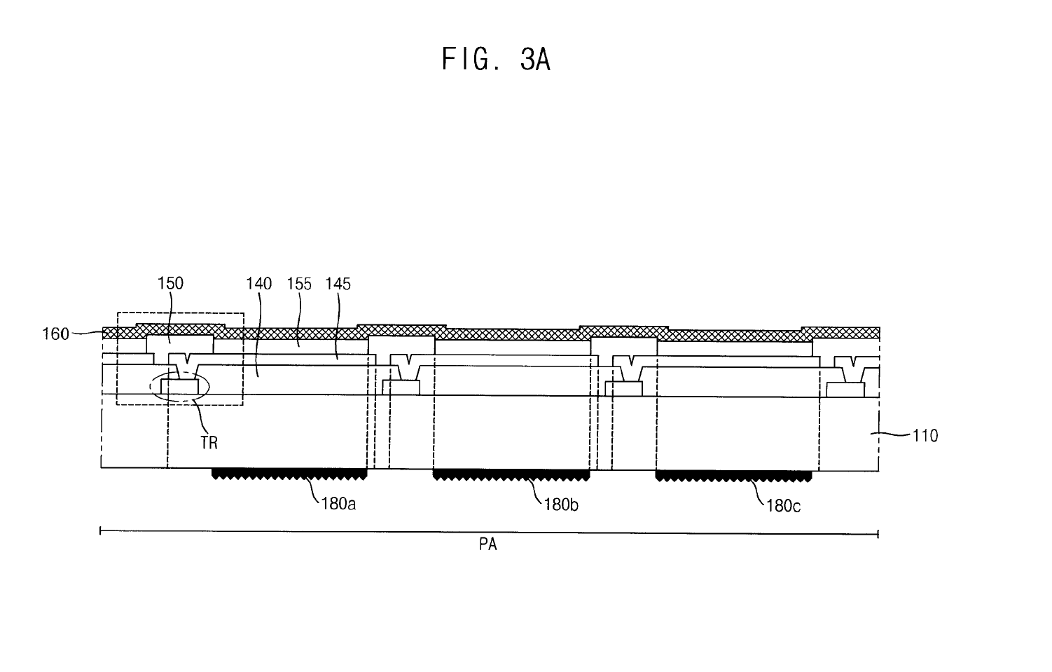

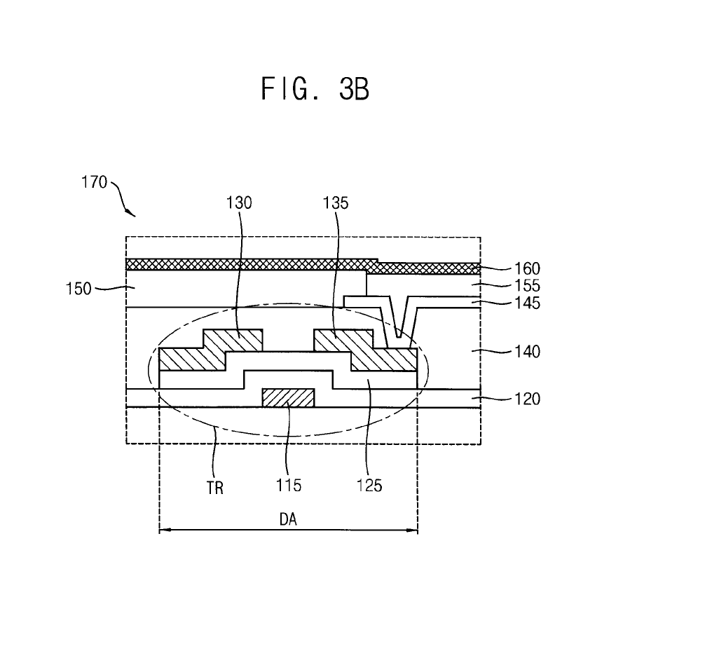

FIG. 1 is a cross-sectional view illustrating an organic light emitting display device according to exemplary embodiments of the present invention. FIG. 2A is a cross-sectional view illustrating an organic light emitting display device including a light transmission controlling member according to exemplary embodiments of the present invention. FIG. 2B is a cross-sectional view magnifying a driving region of the organic light emitting display device of FIG. 2A. FIG. 3A is a cross-sectional view illustrating an organic light emitting display device including a light transmission controlling member according to exemplary embodiments of the present invention. FIG. 3B is a cross-sectional view magnifying a driving region of the organic light emitting display device of FIG. 3A.

Referring to FIGS. 1 to 2B, an organic light emitting display device 100 includes a substrate 110, a display structure 170, and a light transmission controlling member 180.

The substrate 110 may include a transparent insulation material. Further, the substrate 110 may include a flexible substrate. The substrate 110 may have a pixel region PA and a transparent region TA. The pixel region PA of the substrate 110 may have a driving region DA in which a transistor TR is disposed.

The display structure 170 may be disposed on a first face of the substrate 110. The display structure 170 may display an image in accordance with signals applied to the display structure 170. The display structure 170 may include the transistor TR, an insulating interlayer 140, a pixel defining layer 150, a first electrode 145, an organic light emitting layer 155, and a second electrode 160. The transistor TR may include a gate electrode 115, a gate insulation layer 120, an active pattern 125, a source electrode 130, and a drain electrode 135. The transistor TR may be disposed in the driving region DA of the substrate 110.

The light transmission controlling member 180 may be disposed a second face of the substrate 110, which may be opposite or across from the first face of the substrate 110. The light transmission controlling member 180 may transmit an external light passing therethrough or may block the external light. According to aspects of the invention, the light transmission controlling member 180 may operate in connection with the display structure 170. For example, when an electric signal (e.g., a data signal) is applied to the display structure 170, a shape of the light transmission controlling member 180 may be changed. More specifically, when the light transmission controlling member 180 operates by the electric signal applied to the display structure 170, the organic light emitting layer 155 may emit a light. Further, the shape of the light transmission controlling member 180 may vary in accordance with the light emitted from the organic light emitting layer 155. As a result, the external light may be transmitted through the light transmission controlling member 180.

An amount of a transmittance of the external light may vary in accordance with a size of the electric signal. According to aspects of the invention, the organic light emitting display device 100 may have a relatively thin thickness because the display structure 170 and the light transmission controlling member 180 may share the electric signal to control the transmittance of the organic light emitting display device 100. A state in which the shape of the light transmission controlling member 180 varies by applying the electric signal to the light transmission controlling member 180 may be referred to as an ON state. In addition, a state in which the shape of the light transmission controlling member 180 is not changed when the electric signal is applied to the light transmission controlling member 180 may be referred to as an OFF state.

According to aspects of the invention, the light transmission controlling member 180 may include a shape memory polymer. For example, the light transmission controlling member 180 may include polydimethylsiloxane (PDMS). In an example, the light transmission controlling member 180 may include an electro active polymer. As illustrated in FIGS. 2A and 3A, the light transmission controlling member 180 may include a plurality of protruding portions. One or more of the protruding portions may have at least one of a triangular-shaped cross-section, a circular-shaped cross-section, an elliptical-shaped cross-section and a rhombus-shaped cross-section. Further, one or more of the protruding portions may have various three-dimensional shapes, such as an island shape, a line shape, a bar shape, and the like.

When the protruding portions may be spaced apart by a predetermined distance, the organic light emitting display device 100 may block the external light when the organic light emitting display device 100 is in the OFF state. Further, when the organic light emitting display device 100 is in the ON state, the organic light emitting display device 100 may transmit the external light. For example, when the electric signal, such as the data signal, is applied to the light transmission controlling member 180, the light transmission controlling member 180 including the shape memory polymer may be contracted and the shapes of the one or more protruding portions may vary according to the applied electrical signal.

According to aspects of the invention, the amount of the transmission of the external light may be adjusted by a degree of a contraction of the shape memory polymer because the degree of the contraction of the shape memory polymer may vary in accordance with the size or amount of the electric signal. As a result, the transmittance of the organic light emitting display device 100 may be controlled. More specifically, the organic light emitting display device 100 may display images with various transmittances because the amount of the transmittance of the external light passing through the light transmission controlling member 180 may vary by the applied electric signal.

As illustrated in FIG. 2A, at least one the light transmission controlling member 180 corresponding to the entire display structures 170 may be disposed on the second face of the substrate 110. For example, the organic light emitting display device 100 may operate in a white mode for displaying a transparent white color of light. The organic light emitting display device 100 may operate in the white mode if one light transmission controlling member 180 is entirely in the ON state when the organic light emitting layers 155 of the display structure 170 generate a red color of light, a green color of light and a blue color of light, respectively.

Further, as illustrated in FIG. 3A, a plurality of light transmission controlling members 180a, 180b and 180c partially corresponding to the display structures 170 may be disposed on the second face of the substrate 110. The light transmission controlling members 180a, 180b and 180 may independently operate in sub-pixel regions of the pixel region PA. In an example, when the organic light emitting layer 155 of the display structure 170 emits a red color of light, the organic light emitting display device 100 may operate in a red mode for displaying a transparent red color of light. The organic light emitting display device 100 may operate in the red mode when the light transmission controlling member 180a may correspond to only the organic light emitting layer 155 emitting the red color of light.

According to aspects of the invention, a shape of the shape memory polymer of the light transmission controlling member 180 may vary by an external stimulus applied to the light transmission controlling member 180. Further, the organic light emitting display device 100 may additionally include a temperature sensor (not illustrated) connected to the light transmission controlling member 180 to measure a temperature of the light transmission controlling member 180. The shape of the memory polymer of the light transmission controlling member 180 may vary in accordance with the temperature of the light transmission controlling member 180 sensed by the temperature sensor.

In the conventional transparent organic light emitting display device, since an external light leakage may be generated by an external light transmitted from a bottom surface of the conventional transparent organic light emitting display device, the conventional transparent organic light emitting display device may be unable to implement a complete black mode even though the conventional transparent organic light emitting display device is in an OFF state. In addition, since the external light may be reflected when the conventional transparent organic light emitting display device is used in an outdoor environment, a legibility of the conventional transparent organic light emitting display device may be substantially reduced. Further, when the conventional transparent organic light emitting display device is in the ON state, the conventional transparent organic light emitting display device may not display images having various transmittances because the conventional transparent organic light emitting display device may have the same transmittance.

In considerations of these problems associated with the conventional transparent organic light emitting display device, the organic light emitting display device according to exemplary embodiments of the present invention (e.g., the organic light emitting display device 100) may include at least one light transmission controlling member (e.g., the light transmission controlling member 180). The light transmission controlling member 180 may be disposed on the second face of the substrate 110, which may be located opposite of or across from the first face of the substrate 110 and may include a shape memory polymer. For example, the light transmission controlling member 180 may include the plurality of protruding portions.

When the electric signal (e.g., a data signal applied to the display structure 170) is applied to the light transmission controlling member 180, the shape memory polymer may be contracted to change the shapes of the protruding portions. Further, the degree of the contraction of the light transmission controlling member 180 may vary in accordance with the degree of the electric signal applied to the light transmission controlling member 180. As the shape memory polymer is further contracted, the degree of the transmission of the external light may be increased. On the other hand, as the shape memory polymer is further stretched, the degree of the transmission of the external light may be decreased. As a result, when the organic light emitting display device 100 is in the OFF state, the protruding portion of the light transmission controlling member 180 may uniformly block the external light. In addition, when the organic light emitting display device 100 is in the ON state, the transmittance of the organic light emitting display device 100 may be controlled according to the electric signal applied to the light transmission controlling member 180. As a result, the organic light emitting display device 100 may display images having a variety of transmittances.

As illustrated above, the organic light emitting display device 100 may include the light transmission controlling member 180 that shares the electric signal with the display structure 170, so that the transmittance of the organic light emitting display device 100 may be controlled. As a result, the organic light emitting display device 100 may have a thin thickness or a thickness below a reference threshold.

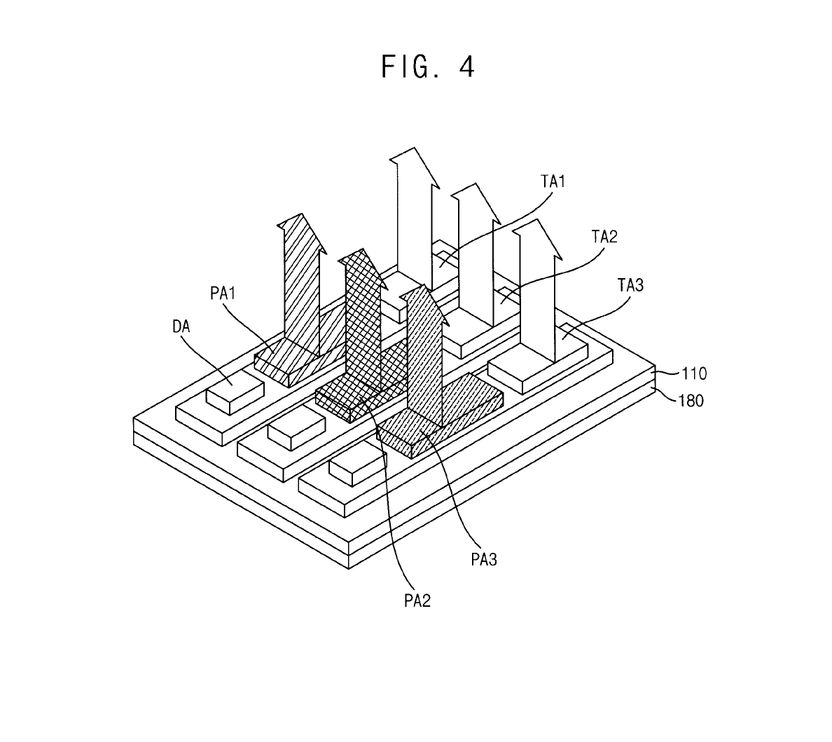

FIG. 4 is a cross sectional view illustrating a white mode of an organic light emitting display device according to exemplary embodiments of the present invention.

Referring to FIG. 4, a red color of light, a green color of light, and a blue color of light may be emitted from a first sub-pixel region PA1, a second sub-pixel region PA2, and a third pixel region PA3, respectively. Thus, an organic light emitting display device may operate in a white mode for displaying a white color of light. A light transmission controlling member 180 may entirely correspond to the first sub-pixel region PA1, the second sub-pixel region PA2, and the third pixel region PA3, so that the light transmission controlling member 180 located beneath the first to the third sub-pixel regions PA1, PA2, and PA3 may be in an ON state. The red color of light, the green color of light, and the blue color of light may be emitted from the first to the third sub-pixel regions PA1, PA2, and PA3, respectively. Simultaneously, an external light may be transmitted through transparent regions TA1, TA2 and TA3. Therefore, the organic light emitting display device may operate in the white mode for displaying a transparent white color of light. The organic light emitting display device may include the light transmission controlling member 180 that controls an amount of a transmittance of the external light in accordance with an applied electric signal, so that the organic light emitting display device may display the white color of light having various transmittances.

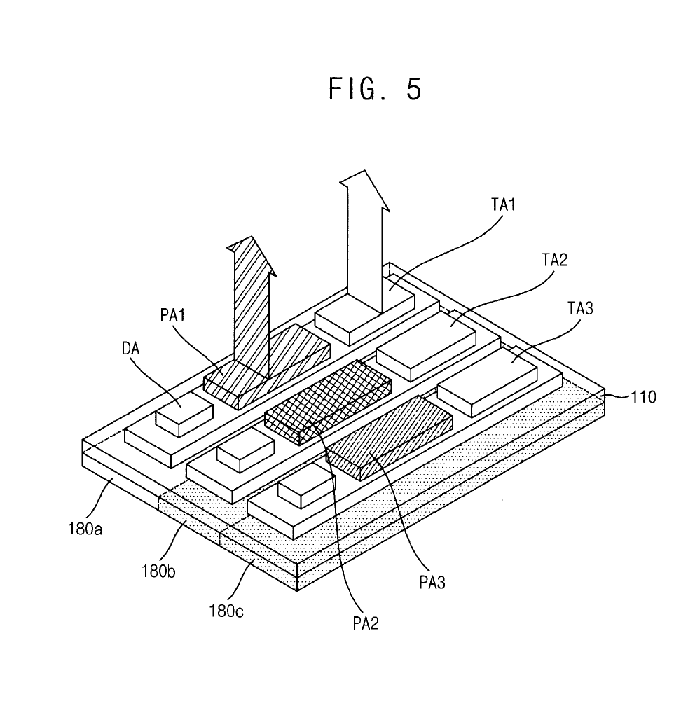

FIG. 5 is a cross sectional view illustrating a red mode of an organic light emitting display device according to exemplary embodiments of the present invention.

Referring to FIG. 5, when a red color of light is emitted from a first sub-pixel region PA1, an organic light emitting display device may operate in a red mode that displays the red color of light. First, second, and third light transmission controlling members 180a, 180b and 180c, respectively, may be disposed in a first to a third sub-pixel regions PA1, PA2 and PA3, respectively. When the red color of light is emitted from the first sub-pixel region PA1, only the light transmission controlling member 180a corresponding to the first sub-pixel region PA1 may be in an ON state. Thus, the red color of light may be emitted from the first sub-pixel region PA1. Simultaneously, an external light may pass through a first transparent region TA1. As a result, the organic light emitting display device may operate in the red mode for displaying a transparent red color of light.

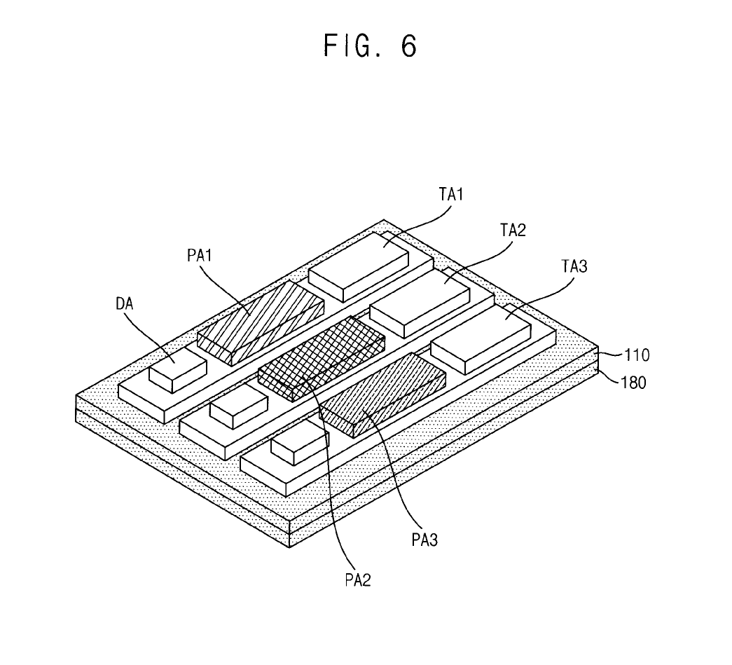

FIG. 6 is a cross sectional view illustrating a black mode of an organic light emitting display device according to exemplary embodiments of the present invention.

Referring to FIG. 6, when lights are not substantially emitted from a first sub-pixel region PA1, a second sub-pixel region PA2, and a third sub-pixel region PA3, a light transmission controlling member 180 may be in an OFF state. As illustrated in FIGS. 2A and 3A, a light transmission controlling member 180 may include protruding portions separated from one another by a predetermined direction, so that an external light may be uniformly blocked even though the light transmission controlling member 180 may be in the OFF state. As described above, the external light may be blocked by the light transmission controlling member 180. Simultaneously, the light may not be emitted from the first to the third sub-pixel region PA1, PA2 and PA3. According to aspects of the invention, the organic light emitting display device may operate in a black mode for displaying a black color of light without leaking or reduced leakage of external light. Although the light transmission controlling member 180 may be entirely disposed beneath a display structure 170 in FIG. 6, aspects of the invention are not limited thereto, such that the light transmission controlling member 180 may be partially disposed beneath the display structure 170.

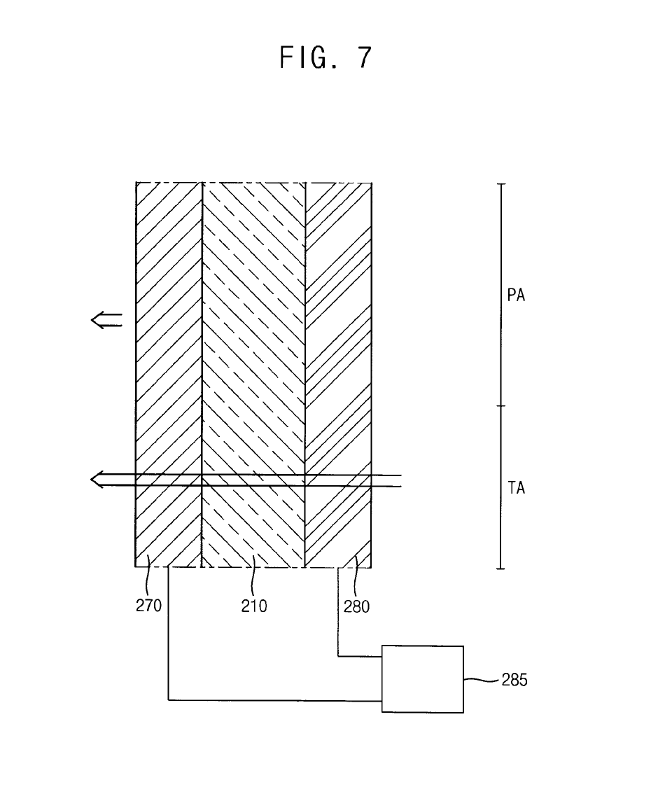

FIG. 7 is a cross-sectional view illustrating an organic light emitting display device according to exemplary embodiments of the present invention. Since the organic light emitting display device 200 of FIG. 2 has a structure substantially the same or similar to the organic light emitting display device 100 of FIG. 1 except for a switching device 285, duplicated descriptions will be omitted.

Referring to FIG. 7, an organic light emitting display device 200 may include a display structure 270 and a switching device 285 connected to a light transmission controlling member 280. According to aspects of the invention, the display structure 270 and the light transmittance controlling member 280 may operate independently. For example, when the display structure 270 is in an ON state, the light transmittance controlling member 280 may be in an ON state or an OFF state. In addition, when the display structure 270 is in an OFF state, the light transmittance controlling member 280 may be in an OFF state or an ON state. When an image is not displayed in a pixel region PA, the light transmission controlling member 280 may be in the OFF state by the switching device 285. Thus, an external light may not be substantially transmitted, and the organic light emitting display device 200 may operate in a black mode for displaying a black color of light. Additionally, when the image is displayed in the pixel region PA, the light transmission controlling member 280 may be in the ON state by the switching device 285. The light transmission controlling member 180 may operate regardless of the electric signal. As a result, the organic light emitting display device 200 may display an image having a uniform transmittance because the organic light emitting display device 200 may have same transmittance. Further, when the image is displayed in the pixel region PA, the organic light emitting display device 200 may display more clear images because the light transmission controlling member 280 may be in the OFF state by the switching device 285 to block the external light.

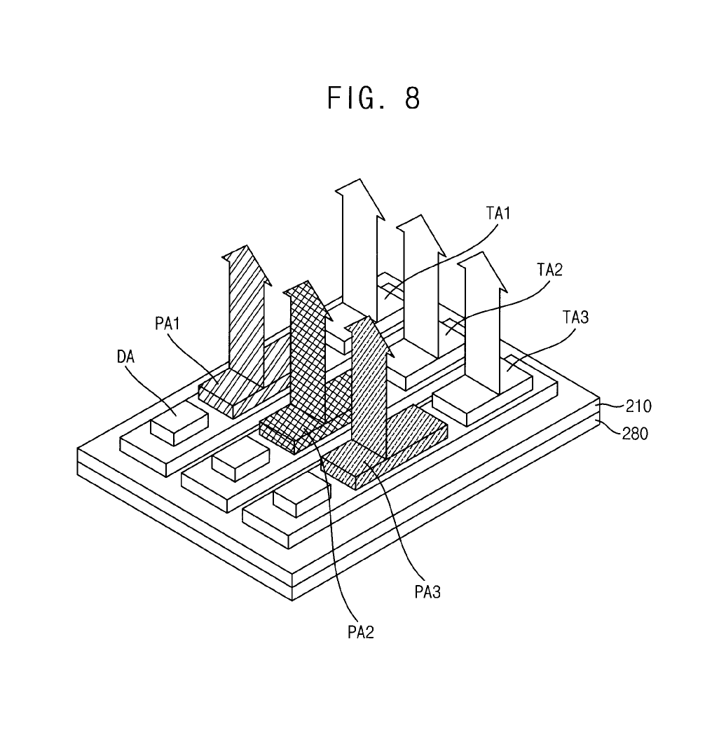

FIG. 8 is a cross sectional view illustrating a white mode of an organic light emitting display device according to exemplary embodiments of the present invention.

Referring to FIG. 8, when a first sub-pixel region PA1, a second sub-pixel region PA2, a third sub-pixel region PA3, and a light transmission controlling member 280 are in an ON state, shapes of protruding portions of the light transmission controlling member 280 may vary, so that an external light may be transmitted by the light transmission controlling member 280. Thus, an organic light emitting display device may operate in a transparent mode. When an electric signal, such as a data signal, is applied to the first sub-pixel region PA1, the second sub-pixel region PA2, the third sub-pixel region PA3, light may be emitted from the first sub-pixel region PA1, the second sub-pixel region PA2, the third sub-pixel region PA3. In addition, the shapes of the protruding portions of the light transmission controlling member 280 may be maintained regardless of the data signal, so that the organic light emitting display device may operate in a white mode for displaying a white color of light, which may have a uniform transmittance.

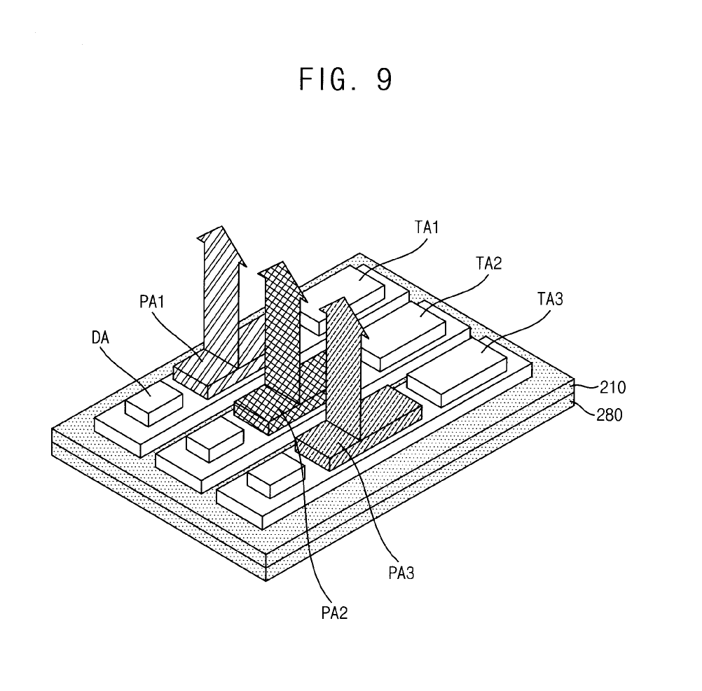

FIG. 9 is a cross sectional view illustrating another white mode of an organic light emitting display device according to exemplary embodiments of the present invention.

Referring to FIG. 9, a red color of light, a green color of light, and a blue color of light may be emitted from a first sub-pixel region PA1, a second sub-pixel region PA2, a third sub-pixel region PA3, respectively. In this case, a light transmission controlling member 280 may be in a OFF state by a switching device 285, so that an external light may not be transmitted through a first transparent region TA1 of a first sub-pixel region PA1, a second transparent region TA2 of a second sub-pixel region PA2, and a third transparent region TA3 of a third sub-pixel region PA3. Therefore, the organic light emitting display device may operate in a white mode that displays a clear white color of light, which may improve legibility.

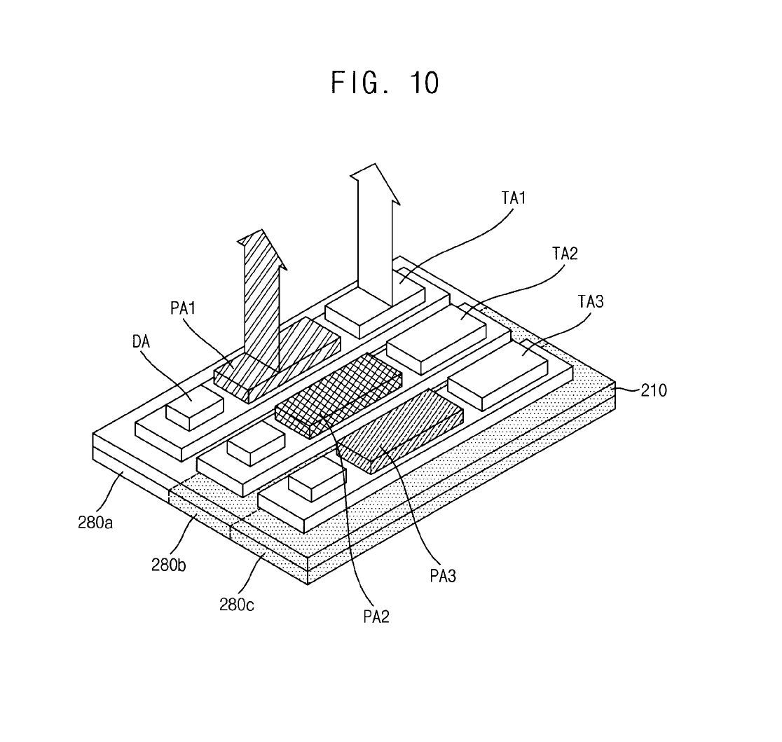

FIG. 10 is a cross sectional view illustrating a red mode of an organic light emitting display device according to exemplary embodiments of the present invention.

Referring to FIG. 10, a red color of light may be emitted from a first sub-pixel region PA1, so that an organic light emitting display device may operate in a red mode for displaying a red color of light. When an electric signal is applied to a first sub-pixel region PA1, the red color of light may be emitted from the first sub-pixel region PA1, and only light transmission controlling member 280a corresponding to the first sub-pixel region PA1 may be in an ON state. A first light transmission controlling member 280a, a second light transmission controlling member 280b, and a third light transmission controlling member 280c may correspond to a first sub-pixel region PA1, a second sub-pixel region PA2, and a third sub-pixel region PA3, respectively. Thus, the red color of light may be emitted from the first sub-pixel region PA1. Simultaneously, an external light may pass through a first transparent region TA1 of the first sub-pixel region PA1. As a result, since a transmittance of the light transmission controlling member 280a may be uniformly maintained, the organic light emitting display device may display a uniformly transparent red color of light.

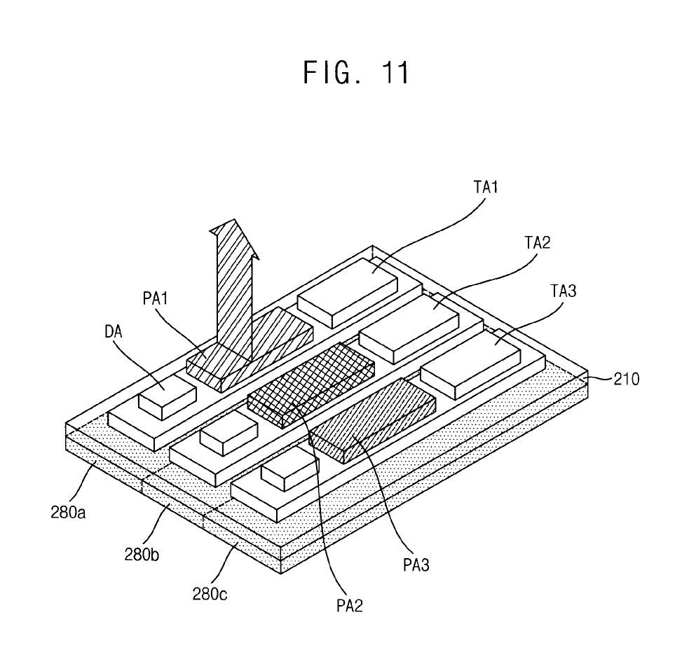

FIG. 11 is a cross sectional view illustrating another red mode of an organic light emitting display device according to exemplary embodiments of the present invention.

Referring to FIG. 11, a first light transmission controlling member 280a corresponding to a first sub-pixel region PA1, a second light transmission controlling member 280b corresponding to a second sub-pixel region PA2, and a third light transmission controlling member 280c corresponding to a third sub-pixel region PA3 may be disposed a second face of the substrate 210. When a red color of light may be emitted from the first sub-pixel region PA1, so that the first sub-pixel region PA1 may emit a clear red color of light because the first light transmission controlling member 280a may block an external light beneath the first sub-pixel region PA1. Thus, the organic light emitting display device may operate in a clear red mode for displaying a clear red color of light. Additionally, the organic light emitting display device may have a clear green mode and/or a clear blue mode using the second light transmission controlling member 280b and/or the third light transmission controlling member 280c.

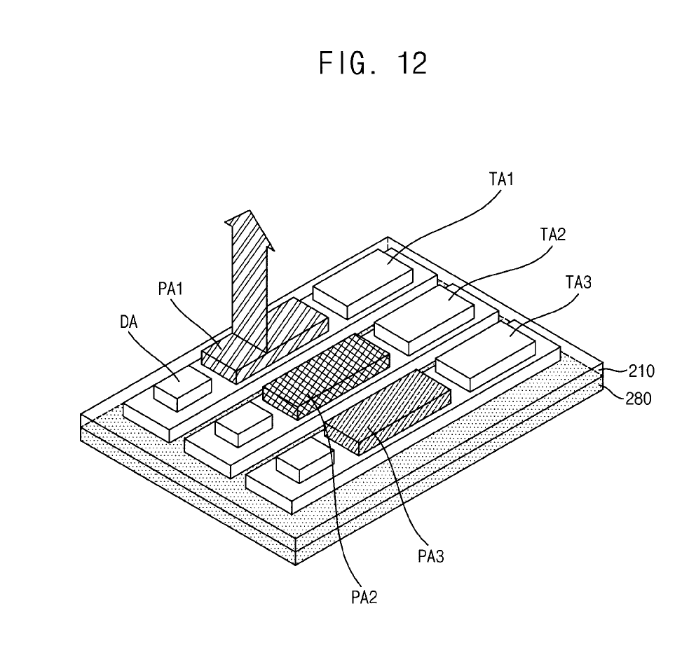

FIG. 12 is a cross sectional view illustrating a black mode of an organic light emitting display device according to exemplary embodiments of the present invention.

Referring to FIG. 12, when a display structure 270 and a light transmission controlling member 280 are in an OFF state, an external light may be completely or substantially blocked by the light transmission controlling member 280 while an external light may not be emitted from the display structure 270. Thus, an organic light emitting display device may operate in a black mode. Since the black mode may be substantially the same as or substantially similar to the black mode described in FIG. 6, duplicated descriptions will be omitted below. Although the light transmission controlling member 280 may be entirely located beneath the display structure 270 in FIG. 12, aspects of the invention are not limited thereto, such that the light transmission controlling member 280 may be partially located beneath the display structure 270.

It will be apparent to those skilled in the art that various modifications and variation can be made in the present invention without departing from the spirit or scope of the invention. Thus, it is intended that the present invention cover the modifications and variations of this invention provided they come within the scope of the appended claims and their equivalents.

What is claimed is:

1. An organic light emitting display device, comprising:
a substrate;
a display structure disposed on a first face of the substrate; and
a light transmission controlling member disposed on a second face of the substrate, the second face opposed to the first face,
wherein the light transmission controlling member comprises a shape memory polymer configured to change its shape to control an amount of an external light passing through the light transmission controlling member.

2. The organic light emitting display device of claim 1, wherein the light transmission controlling member further comprises a plurality of protruding portions.

3. The organic light emitting display device of claim 2, wherein one or more of the protruding portions has at least one of a triangular-shaped cross-section, a circular-shaped cross-section shape, an elliptical-shaped cross-section or a rhombus-shaped cross-section.

4. The organic light emitting display device of claim 1, wherein the display structure operates in connection with the light transmission controlling member.

5. The organic light emitting display device of claim 2, wherein when an electric signal is applied to the light transmission controlling member, the light transmission controlling member is contracted to change a shape of one or more of the protruding portions.

6. The organic light emitting display device of claim 5, wherein the electric signal comprises a data signal applied to the display structure.

7. The organic light emitting display device of claim 6, wherein a degree of a contraction of the light transmission controlling member varies according to a size of the data signal applied to the display structure.

8. The organic light emitting display device of claim 7, wherein an amount of a transmission of the external light varies according to the degree of the contraction of the light transmission controlling member.

9. The organic light emitting display device of claim 1, wherein the display structure and another display structure are disposed on the first face of the substrate, and the light transmission controlling member corresponding to the display structure and another light transmission controlling member corresponding to the other display structure are disposed the second face of the substrate.

10. The organic light emitting display device of claim 1, wherein the display structure and another display structure are disposed on the first face of the substrate, and one light transmission controlling member corresponding to both the display structure and the other display structure are disposed the second face of the substrate.

11. The organic light emitting display device of claim 1, further comprising:
a switching device electrically connected to the display structure and the light transmission controlling member.

12. The organic light emitting display device of claim 11, wherein the display structure and the light transmission controlling member operate independently.

13. The organic light emitting display device of claim 12, wherein when the display structure and the light transmission controlling member are in an on-state, a light is emitted from the display structure and an external light is transmitted through the light transmission controlling member.

14. The organic light emitting display device of claim 12, wherein when the display structure is in an on-state and the light transmission controlling member is in an off-state, a light is emitted from the display structure and an external light is blocked by the light transmission controlling member.

15. The organic light emitting display device of claim 12, wherein when the display structure and the light transmission controlling member are in an off-state, a light is not emitted from the display structure and the external light is blocked by the light transmission controlling member.

16. The organic light emitting display device of claim 12, wherein when the display structure is in an off-state and the light transmission controlling member is in an on-state, a light is not emitted from the display structure and the external light is transmitted through the light transmission controlling member.

17. The organic light emitting display device of claim 2, wherein shapes of the protruding portions of the light transmission controlling member vary according to temperature.

18. The organic light emitting display device of claim 17, further comprising:
a temperature sensor connected to the light transmission controlling member to sense the temperature.

19. The organic light emitting display device of claim 2, wherein shapes of the protruding portions vary according to an external stimulus applied to the light transmission controlling member.

20. The organic light emitting display device of claim 1, wherein the light transmission controlling member further comprises an electro active polymer.
